(19) United States
(12) Patent Application Publication
(10) Pub. No.: US 2026/0288362 A1
(43) Pub. Date: Sep. 24, 2026

(54) COMBINING ALP COARSE WITH ISPP FINE PROGRAMMING

(71) Applicant: Micron Technology, Inc., Boise, ID (US)

(72) Inventors: Yu-Chung Lien, San Jose, CA (US); Zhenming Zhou, San Jose, CA (US)

(21) Appl. No.: 19/084,349

(22) Filed: Mar. 19, 2025

(51) Int. Cl. G06F 3/06

(52) U.S. Cl. CPC G06F 3/0655; G06F 3/0604; G06F 3/0679

(57) ABSTRACT

A system and method for reading data from a memory device. The system and method receive a request to program data to an individual word line (WL) of the memory device. The system and method, in response to receiving the request to program the data, perform a coarse programming operation using a first type of programming scheme as a first programming phase associated with programming the data to the individual WL. The system and method perform, as a second programming phase, a fine programming operation using a second type of programming scheme after performing the coarse programming operation to complete programming the data to the individual WL of the memory device.

### TECHNICAL FIELD

This disclosure relates generally to memory sub-systems and, more specifically, to providing adaptive media management for memory components, such as memory dies.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory sub-system, in accordance with some examples.

FIG. 2 illustrates diagrams of ISPP and ALP program sequences, in accordance with some examples.

FIG. 3 illustrates an example programming sequence alternating between ISPP and ALP, in accordance with some examples.

FIG. 4 illustrates a diagram of operations performed using the media operations manager, in accordance with some examples.

FIG. 5 illustrates a diagram of operations performed using the media operations manager, in accordance with some examples.

FIG. 6 is a block diagram of an example computer system, in accordance with some examples.

### DETAILED DESCRIPTION

The present disclosure configures a system component, such as a memory sub-system controller to perform two-phase programming operations using different programming schemes for each phase. Specifically, the controller performs a coarse programming operation using an all-level programming (ALP) scheme as a first programming phase. The ALP scheme applies programming pulses to program memory cells to their target levels simultaneously by controlling channel boosting for each target level. After the coarse programming phase, the controller performs a fine programming operation using an incremental step program pulse (ISPP) scheme that uses a smaller voltage step size to achieve more accurate voltage threshold placement. This two-phase approach improves programming time compared to using ISPP alone or ALP alone for both phases while maintaining programming accuracy through the fine programming phase. The approach can be beneficial for cloud storage optimized (CSO) architectures with increased page sizes. The controller can implement this programming sequence across multiple sub-blocks of word lines in an interleaved fashion, alternating between programming different word lines to optimize overall system performance and decrease the amount of time spent programming data to a memory device. This improves the overall efficiency of the memory sub-system.

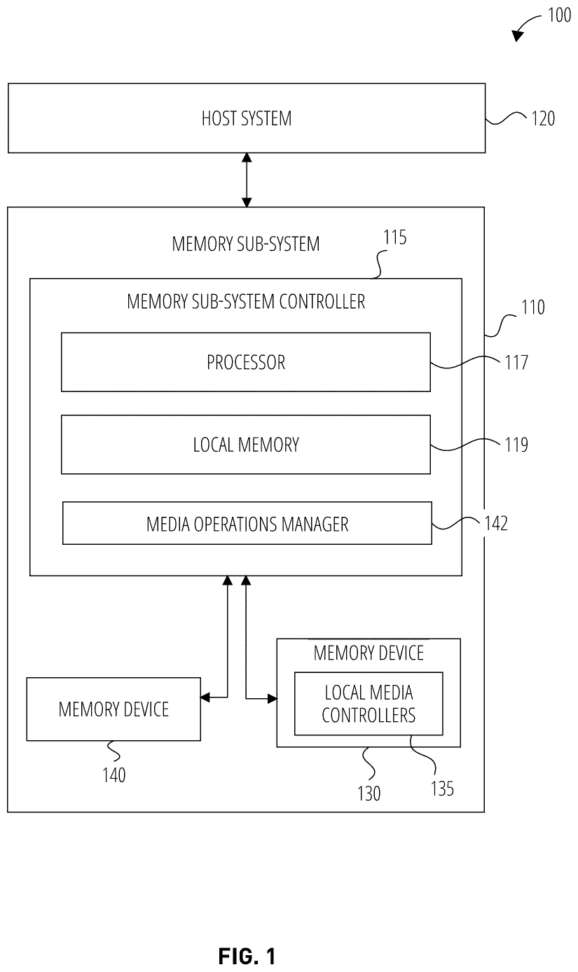

A memory sub-system can be a storage device, a memory module (memory component), or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written, for example as initiated by the firmware, is hereinafter referred to as “garbage collection data.” “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest areas that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package.

In conventional systems using ISPP (Incremental Step Pulse Programming), multi-level memory cells (e.g., in multi-level cell (MLC), tri-level cell (TLC), and/or quad-level cell (QLC) memory devices) are programmed level-by-level. Namely, lower levels are programmed first, and higher levels are programmed last. ALP represents a fundamentally different approach to programming NAND memory cells. Instead of programming levels sequentially, ALP simultaneously programs all levels (e.g., Levels 0-7 in TLC memory devices) by applying different bit line biases to achieve different boosting potentials (Vpillar) for each memory cell. ALP uses a single program voltage pulse while controlling individual channel potentials to reach different threshold voltages for different cells simultaneously. ALP may require only 4-6 pulses to complete programming, compared to ISPP's 10-15 pulses. During each pulse, ALP programs cells to roughly their target positions across all levels at once, then uses subsequent pulses to fine-tune the threshold voltage distributions.

In conventional systems using ISPP programming, multi-level memory cells are programmed in an inefficient sequential manner, where lower levels must be programmed first before programming higher levels. This level-by-level approach can require a significant number of programming pulses to complete the programming operation. The sequential nature of conventional ISPP programming creates several inefficiencies. First, the need to program each level separately results in longer overall programming times since each level needs to wait for the previous level to complete before it can begin. Second, the large number of required programming pulses (e.g., 10-15) increases power consumption and programming latency.

Additionally, conventional ISPP systems use the same programming scheme with fixed voltage step sizes for all programming operations, which fails to optimize for different programming needs at different stages. This one-size-fits-all approach leads to unnecessary precision during early programming stages while still using many programming loops to achieve final threshold voltage placements.

For CSO architectures with increased page sizes, these inefficiencies become even more pronounced. The conventional approach can result in significant performance degradation in programming times. This performance impact makes conventional programming schemes less useful. The level-by-level programming sequence also requires maintaining consistent voltage thresholds across multiple programming phases, increasing system complexity and the likelihood of programming errors if precise voltage control is not maintained throughout the entire sequence.

The present disclosure addresses these technical challenges by providing a memory sub-system controller (memory controller) that can perform two-phase programming operations using different programming schemes optimized for each phase. Specifically, the controller can perform coarse programming using a first type of programming scheme, such as an ALP scheme. The ALP scheme can simultaneously program multiple levels by applying different bit line biases to achieve different boosting potentials for each memory cell and may require only 4-6 programming pulses compared to the 17 pulses required by conventional ISPP program approaches. The controller then performs fine programming using a second programming scheme, such as an ISPP scheme, with smaller voltage step sizes to achieve precise threshold voltage placement. This hybrid approach improves programming time (e.g., reduces the amount of time spent programming data to one or more WLs) while maintaining programming accuracy through the fine programming phase. The controller can implement this programming sequence across multiple sub-blocks in an interleaved fashion between WLs, alternating between performing coarse operations (e.g., using the first programming scheme) on one word line while performing fine operations (e.g., using the second programming scheme) on another word line to optimize overall system performance. This approach can be particularly beneficial for CSO architectures with increased page sizes, where the performance improvements help mitigate the programming time degradation that occurs with larger page sizes.

In some examples, a system includes a memory device, and a processing device operatively coupled to the memory device. The processing device can receive a request to program data to an individual WL of the memory device. In response, the processing device performs a coarse programming operation using a first type of programming scheme as a first programming phase, followed by a fine programming operation using a second type of programming scheme as a second programming phase to complete programming the data. In some cases, the first type of programming scheme includes an ALP scheme that applies programming pulses to program memory cells to their target levels in a single programming phase. The ALP scheme controls channel boosting for each target level by toggling bit line biases at different Vpass thresholds and ramping the staircase Vpass for unselected WLs. The second type of programming scheme may include an ISPP programming scheme that uses a smaller voltage step size compared to the ALP scheme. This smaller step size enables more accurate voltage threshold placement during the fine programming phase.

During the coarse programming operation, the processing device may toggle bit line timing at different Vpass bias (staircase voltage) to control channel boosting. Following the staircase waveform, a program pulse with a specified voltage step size may be applied. In some implementations, program verify operations are performed between programming loops during both the coarse and fine programming operations to ensure proper programming.

The processing device may program multiple sub-blocks (SBs) of the individual WL in sequence. In some cases, this involves alternating between programming the individual WL and an adjacent WL in an interleaved sequence. For example, the processing device may perform a first coarse programming operation on each SB of the individual WL, followed by a second coarse programming operation on a first SB of an adjacent WL. While performing a third coarse programming operation on a second SB of the adjacent WL, the processing device may simultaneously perform a first fine programming operation on the first SB of the individual WL.

The memory device may include various types of memory cells, including multi-level cell (MLC), tri-level cell (TLC), or quad-level cell (QLC) memory devices. In some implementations, the memory device specifically includes a QLC memory device or a three-dimensional (3D) NAND device. The described operations can be implemented through instructions stored on a non-transitory machine-readable storage medium that, when executed by a processing device, cause the processing device to perform the programming operations.

These operations can also be implemented as a method including the same programming sequence using the first type of programming scheme for coarse programming and the second type for fine programming.

Though various examples are described herein as being implemented with respect to a memory sub-system (e.g., a controller of the memory sub-system), some or all of the portions of an embodiment can be implemented with respect to a host system, such as a software application or an operating system of the host system.

FIG. 1 illustrates an example computing system 100 that includes a memory sub-system 110, in accordance with some examples. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IOT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some examples, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND flash memory and write-in-place memory, such as a 3D cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells, such as multi-level cells (MLCs), tri-level cells (TLCs), quad-level cells (QLCs), and penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or BSs. As used herein, a block comprising SLCs can be referred to as a SLC block, a block including MLCs can be referred to as a MLC block, a block comprising TLCs can be referred to as a TLC block, and a block including QLCs can be referred to as a QLC block.

Although non-volatile memory components such as NAND-type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data (e.g., performing GC operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some examples, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., LBA, namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some examples, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controller 135) for media management within the same memory device package. An example of a managed memory device is a managed NAND (MNAND) device. Any operation discussed as being performed by the memory sub-system controller 115 can be similarly performed by the local media controllers 135 and vice versa.

The media operations manager 142 can perform two-phase programming operations using different programming schemes optimized for each phase. Specifically, the media operations manager 142 can perform coarse programming using a first type of programming scheme, such as an ALP scheme. The ALP scheme can simultaneously program multiple levels by applying different bit line biases to achieve different boosting potentials for each memory cell and may require only 4-6 programming pulses compared to the 17 pulses required by conventional ISPP program approaches. The media operations manager 142 can then perform fine programming using a second programming scheme, such as an ISPP scheme, with smaller voltage step sizes to achieve precise threshold voltage placement. This hybrid approach improves programming time (e.g., reduces the amount of time spent programming data to one or more WLs) while maintaining programming accuracy through the fine programming phase. The media operations manager 142 can implement this programming sequence across multiple sub-blocks in an interleaved fashion between WLs, alternating between performing coarse operations (e.g., using the first programming scheme) on one word line while performing fine operations (e.g., using the second programming scheme) on another word line to optimize overall system performance. This approach can be particularly beneficial for CSO architectures with increased page sizes, where the performance improvements help mitigate the programming time degradation that occurs with larger page sizes.

The key difference between coarse and fine programming phases can be explained through their distinct voltage step sizes and programming approaches. In the coarse programming phase using ALP, the media operations manager 142 employs larger voltage step sizes while simultaneously programming all levels by controlling bit line boosting potentials for different target levels. The coarse phase can be performed in 4-6 programming pulses and can utilize a staircase waveform during the voltage pass phase. Different bit lines can be turned on at different timing intervals to achieve different target levels. This phase prioritizes speed over precision, focusing on rough placement of threshold voltages.

The voltage step size refers to the incremental increase in voltage applied to the selected WL during programming operations. During the coarse programming phase using ALP, a larger voltage step size is applied to the selected WL, while unselected word lines remain at a pass voltage level. This larger step size allows for faster but rougher programming, as the selected WL receives larger voltage increments during each programming pulse. The staircase waveform applied during the voltage pass phase creates different voltage levels on the selected WL, while simultaneously controlling bit line biases to achieve different boosting potentials (Vpillar) for different target levels.

The voltage difference between the selected word line and unselected WLs creates the programming conditions. By using larger voltage steps on the selected WL during coarse programming, cells can be programmed more quickly but with less precision. The bit line boosting potentials work in conjunction with these WL voltages. Namely, when a bit line (BL) is turned on at a particular timing interval during the staircase waveform, it allows the corresponding cell to be programmed to a specific target level based on the voltage difference between the selected WL and the channel potential created by the bit line bias. This approach differs from conventional programming where the voltage on the selected WL would be increased in smaller increments relative to the pass voltage on unselected WL. The larger step size during coarse programming means the voltage on the selected word line increases more aggressively compared to unselected word lines, trading precision for programming speed.

The fine programming phase, such as using ISPP, employs smaller voltage step sizes to achieve more precise control over the final threshold voltage placement. This phase programs levels sequentially with incremental steps and can be performed in about 20 programming pulses. The fine phase can use fixed voltage levels with consistent incremental increases between programming loops, focusing on achieving exact threshold voltage placement to ensure accurate final states.

When programming a cell to a specific threshold voltage, the coarse phase first quickly programs the cell close to its target level using larger voltage steps and bit line boosting control. Following this, the fine phase makes small, precise adjustments using smaller voltage increments to achieve the exact desired threshold voltage. Throughout both phases, program verify operations are performed between programming loops to ensure proper programming.

This combined approach leverages the speed advantages of ALP's simultaneous programming with the precision of ISPP's fine-tuning.

Any discussion with respect to the memory device 130 can similarly be applied to the memory device 140. Any function pertaining to the local media controllers 135 can, in some cases, be performed by the device) memory sub-system controller 115.

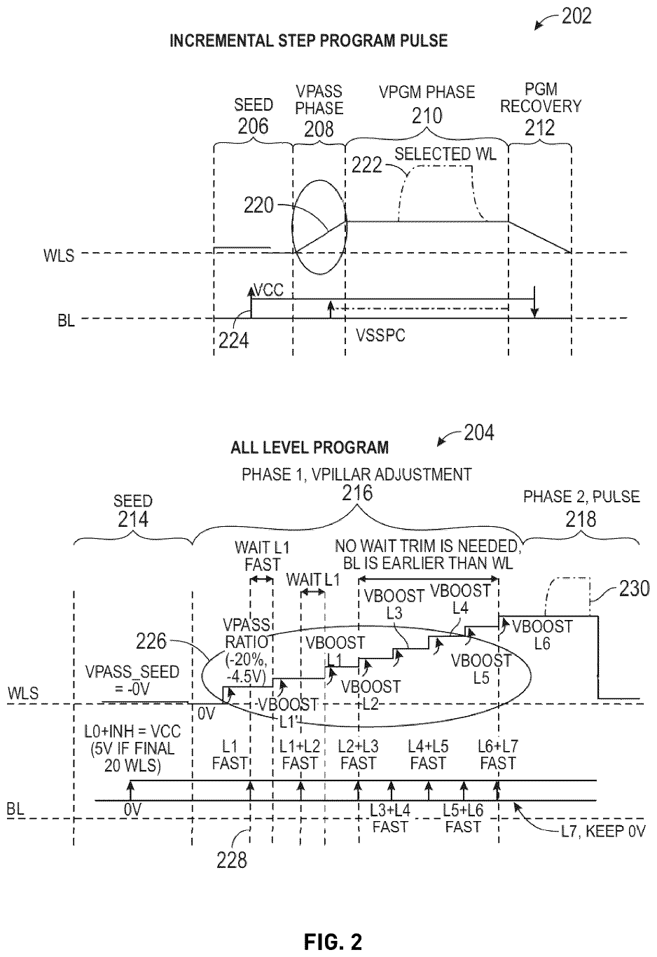

FIG. 2 illustrates a ISPP diagram 202 and an ALP diagram 204, in accordance with some examples. Namely, FIG. 2, illustrates two distinct programming approaches or types.

These include the ISPP programming scheme shown in the ISPP diagram 202, which is used for fine programming, and the ALP programming scheme shown in the ALP diagram 204, which is used for coarse programming.

The ALP coarse programming sequence begins with an ALP seed phase 214. The ALP seed phase 214 is where the WLs are initialized at a low voltage level (Vpass_seed=0V).

During this phase, the BLs are set to either VCC for inhibited cells or OV for cells to be programmed. Following the seed phase, the ALP scheme enters the ALP first Vpass phase 216, which implements a distinctive staircase waveform pattern. During this phase, the selected WL voltage increases in steps while different BLs are activated at specific timing intervals. This staircase approach allows for simultaneous programming of multiple levels by controlling the boosting potentials for each target level.

The ALP second Vpass phase 218 continues the staircase pattern, with BL biases being adjusted to achieve different boosting potentials (Vpillar) for different target levels. This phase is important for establishing the proper channel potentials that determine the final threshold voltages of the cells. During the ALP voltage pass phases, the WL voltage follows a controlled staircase pattern where it remains at specific levels while waiting for BL bias stabilization. This allows for precise control of the boosting conditions for each target level. The BL voltages during ALP are dynamically controlled, with different BLs being turned on at different times corresponding to their target programming levels. This creates different boosting potentials that determine how much each cell will be programmed. For example, an individual level bit line boosting 228 represents the individual level BL boosting that occurs during the ALP coarse programming operation. The individual level bit line boosting 228 shows how different BLs are controlled to achieve different boosting potentials for different target levels simultaneously.

During the voltage pass phase, the BLs are turned on at different timing intervals, creating distinct channel potentials that determine how much each cell will be programmed. This individual level bit line boosting 228 is a key feature that enables ALP to program multiple cells to different threshold voltages in parallel, as opposed to the sequential programming approach used in ISPP. The BL boosting control shown by individual level bit line boosting 228 works in conjunction with the staircase voltage 226 (e.g., staircase waveform) applied to the WLs to achieve the simultaneous programming of multiple levels during the coarse programming phase.

The ALP programming scheme uses a larger voltage step size during the programming phase where the selected WL program pulse 230 is applied, which allows for faster but rougher programming. This is referred to as the coarse programming operation. This larger step size contributes to the ability to complete the coarse programming phase in only 4-6 programming pulses.

For the fine programming phase, the media operations manager 142 performs the operations shown in the ISPP diagram 202. The ISPP diagram 202 begins with an ISPP seed phase 206 where initial conditions are established. The WLs and BLs are set to their initial voltages during this phase. The ISPP Vpass phase 208 follows, where unselected WLs are raised to their pass voltage levels. Unlike ALP, this is a direct ramping without the staircase pattern.

During the ISPP voltage program phase 210, the selected WL receives programming pulses with a smaller voltage step size. This smaller step size allows for more precise threshold voltage placement during the fine programming phase. The ISPP scheme includes an ISPP program recovery phase 212 after each programming pulse, where voltages are returned to their initial states before the next programming cycle begins.

The ISPP approach can require more programming loops compared to ALP, but provides more precise control over the final threshold voltage placement. Between programming loops in both schemes, program verify operations can be performed by the media operations manager 142 to ensure proper programming of the cells. These verify operations help maintain programming accuracy throughout both the coarse and fine programming phases.

The selected WL program pulse 222 in both schemes receives different voltage patterns. Namely, the staircase pattern is applied by the media operations manager 142 for ALP and the incremental step increases is applied by the media operations manager 142 for ISPP.

The unselected WLs 220 maintain pass voltages during programming. The bit line 224 behavior differs between the two programming schemes. In ALP, the bit line are controlled to achieve different boosting potentials simultaneously, while in ISPP, the bit lines 224 maintain more consistent voltages during programming.

The combination of these two schemes-ALP for coarse programming followed by ISPP for fine programming-leverages the speed advantages of ALP's simultaneous multi-level programming with the precision of ISPP's fine-tuning capability. This hybrid approach allows for both efficient initial programming through ALP's larger voltage steps and staircase waveform, followed by precise threshold voltage placement using ISPP's smaller voltage steps, resulting in improved overall programming performance while maintaining accuracy.

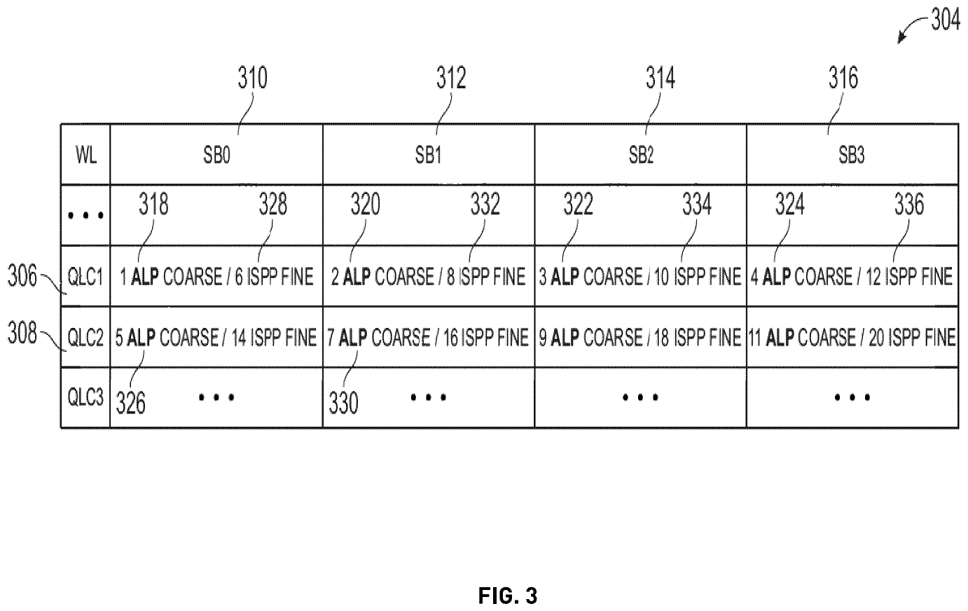

FIG. 3 illustrates an example program sequence diagram 304 alternating between ISPP and ALP, in accordance with some examples. Namely, the program sequence diagram 304 represents programming multiple WLs using a combination of different types of program sequences. For example, FIG. 3 illustrates a program sequence diagram 304 showing how the media operations manager 142 performs coarse and fine programming operations across multiple WLs and SBs.

The program sequence diagram 304 shows two WLs including individual WL 306 (e.g., QLC1, a first QLC WL) and additional WL 308 (QLC2, a second QLC WL). The individual WL 306 and the additional WL 308 can each be divided into four SBs (e.g., SB0-SB3) labeled as first sub-block 310, second sub-block 312, 314, and fourth sub-block 316.

In response to receiving a request to program a set of data to one or more WLs (e.g., from internal operations, such as garbage collection, and/or from the host system 120), the media operations manager 142 begins by performing a first coarse programming operation 318 on the first sub-block of QLC 1, such as the first sub-block 310 of the individual WL 306. This operation uses the ALP scheme with larger voltage step sizes to quickly program the cells to rough target levels. Following this, the media operations manager 142 performs a second coarse programming operation 320 on the remaining SBs of the individual WL 306, continuing the coarse programming phase with the same ALP parameters. Namely, the media operations manager 142 can perform the third coarse programming operation 322 and the fourth coarse programming operation 324 to complete coarse programming of each of the SBs of the individual WL 306.

After completing the coarse programming of individual WL 306, the media operations manager 142 initiates a fifth coarse programming operation 326 on the first SB of the additional WL 308, which can be adjacent to the individual WL 306. The media operations manager 142 then begins interleaving operations between the two WLs. For example, while or after performing the fifth coarse programming operation 326 on the second SB of the additional WL 308, the media operations manager 142 performs a first fine programming operation 328 on the first SB of the individual WL 306. This interleaved sequence continues as the media operations manager 142 performs a sixth coarse programming operation 330 on the second SB of the additional WL 308 while executing a second fine programming operation 332 on the second SB of individual WL 306.

The media operations manager 142 maintains this pattern, performing a third fine programming operation 334 and fourth fine programming operation 336 on the remaining SBs of individual WL 306 while performing coarse programming operations on the remaining SBs of the additional WL 308. Finally, the media operations manager 142 completes the sequence with a fourth fine programming operation 336 on the fourth SB of the individual WL 306.

Throughout this sequence, the media operations manager 142 alternates between performing coarse ALP operations with larger voltage steps and fine ISPP operations with smaller voltage steps.

In some cases, after completing the fine programming operations on all SBs of the individual WL 306, the media operations manager 142 begins performing fine programming operations on the additional WL 308. The media operations manager 142 performs a second fine programming operation using the ISPP scheme on the first SB of the additional WL 308 after completing all fine programming operations on the individual WL 306. This sequencing ensures that the precise threshold voltage placement achieved through the fine programming phase (using smaller voltage steps) is maintained for each WL before moving to fine programming operations on subsequent WLs.

The interleaved programming sequence continues in this pattern, where coarse programming operations using ALP (with larger voltage steps) are performed on subsequent WLs while fine programming operations using ISPP are completed on the previous WL. This approach optimizes programming performance by allowing simultaneous operations across different WLs while ensuring precise threshold voltage placement is achieved through the fine programming phase before moving to the next WL.

This interleaved programming approach allows the media operations manager 142 to optimize overall system performance by efficiently utilizing programming resources across multiple WLs and sub-blocks simultaneously. The sequence demonstrates how the media operations manager 142 implements the two-phase programming approach, using ALP for coarse programming to quickly establish rough threshold voltages, followed by ISPP for fine programming to achieve precise final threshold voltage placement.

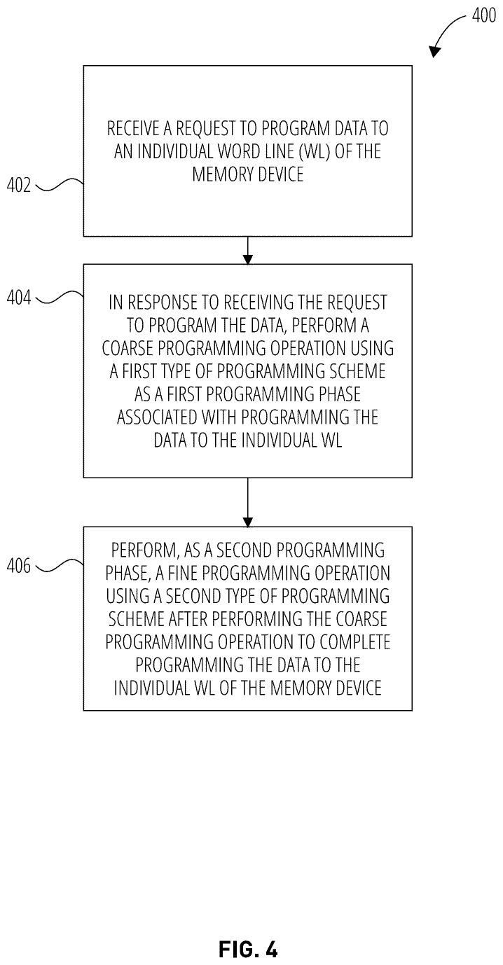

FIG. 4 illustrates a diagram 400 of operations performed using the media operations manager 142, in accordance with some examples. The method or process of diagram 400 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 400 is performed by the memory sub-system controller 115, local media controllers 135, and/or subcomponents of the memory sub-system controller 115 and/or local media controllers 135 of FIG. 1. In these examples, the method or process of diagram 400 can be performed, at least in part, by the media operations manager 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example, other process flows are possible.

Referring now to FIG. 4, the method begins at operation 402 with the media operations manager 142 receiving a request to program data to an individual WL of the memory device 130, the ALP operation simultaneously programming multiple levels of the memory device 130. At operation 404, the media operations manager 142 in response to receiving the request to program the data, performs a coarse programming operation using a first type of programming scheme as a first programming phase associated with programming the data to the individual WL. At operation 406, the media operations manager 142 performs, as a second programming phase, a fine programming operation using a second type of programming scheme after performing the coarse programming operation to complete programming the data to the individual WL of the memory device 130.

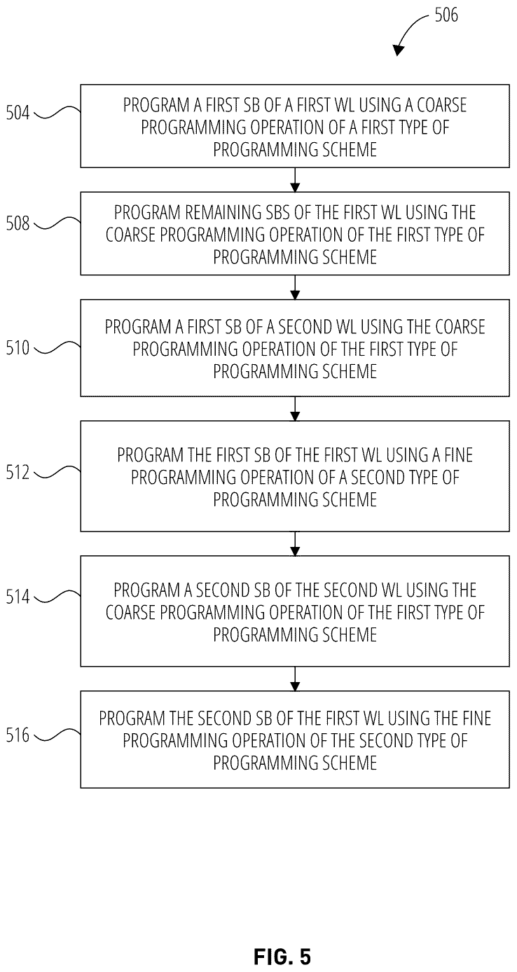

FIG. 5 illustrates a diagram 506 of operations performed using the media operations manager 142, in accordance with some examples. The method or process of diagram 506 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 506 is performed by the memory sub-system controller 115, local media controllers 135, and/or subcomponents of the memory sub-system controller 115 and/or local media controllers 135 of FIG. 1. In these examples, the method or process of diagram 506 can be performed, at least in part, by the media operations manager 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example, other process flows are possible.

Referring to FIG. 5, the media operations manager 142 performs a sequence of interleaved programming operations across multiple WLs and SBs. The sequence begins at operation 504, where the media operations manager 142 programs a first SB of a first WL using a coarse programming operation with the first type of programming scheme (e.g., ALP). At operation 508, the media operations manager 142 continues by programming the remaining SBs of the first WL using the same coarse programming operation with the first type of programming scheme.

Following this, at operation 510, the media operations manager 142 programs a first SB of a second WL using the coarse programming operation with the first type of programming scheme. At operation 512, while the first SB of the second WL is being programmed or after the first SB of the second WL is programmed, the media operations manager 142 returns to the first WL to program the first SB of the first WL using a fine programming operation with a second type of programming scheme (e.g., ISPP). The interleaved sequence continues at operation 514, where the media operations manager 142 programs a second SB of the second WL using the coarse programming operation with the first type of programming scheme.

Finally, at operation 516, the media operations manager 142 programs the second SB of the first WL using the fine programming operation with the second type of programming scheme.

Throughout this sequence, the media operations manager 142 alternates between performing coarse ALP operations with larger voltage steps on one WL while performing fine ISPP operations with smaller voltage steps on another WL. This interleaved approach optimizes programming performance by efficiently utilizing system resources across multiple WLs and sub-blocks simultaneously.

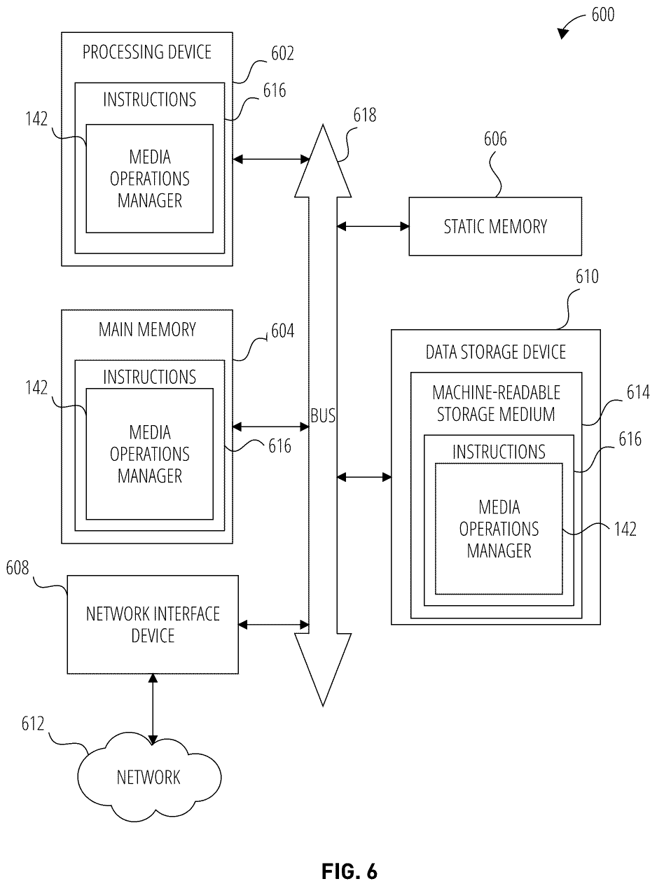

FIG. 6 illustrates an example machine in the form of a computer system 600 within which a set of instructions can be executed for causing the machine to perform any one or more of the methodologies discussed herein. In some examples, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., ROM, flash memory, DRAM such as SDRAM or Rambus DRAM (RDRAM), etc.), a static memory 606 (e.g., flash memory, static random access memory (SRAM), etc.), and a data storage device 610, which communicate with each other via a bus 618.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application-specific integrated circuit (ASIC), a field programmable gate array (FPGA), a digital signal processor (DSP), a network processor, or the like. The processing device 602 is configured to execute instructions 616 for performing the operations and steps discussed herein. The computer system 600 can further include a network interface device 608 to communicate over a network 612.

The data storage device 610 can include a machine-readable storage medium 614 (also known as a computer-readable medium) on which is stored one or more sets of instructions 616 or software embodying any one or more of the methodologies or functions described herein. The instructions 616 can also reside, completely or at least partially, within the main memory 604 and/or within the processing device 602 during execution thereof by the computer system 600, the main memory 604 and the processing device 602 also constituting machine-readable storage media. The machine-readable storage medium 614, data storage device 610, and/or main memory 604 can correspond to the memory sub-system 110 of FIG. 1.

In one example, the instructions 616 include instructions to implement functionality corresponding to providing block failure protection for a zone memory sub-system as described herein (e.g., the REH component 113 of FIG. 1). While the machine-readable storage medium 614 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

Example 1. A system comprising: a memory device; and a processing device, operatively coupled to the memory device, configured to perform operations comprising: receiving a request to program data to an individual word line (WL) of the memory device; in response to receiving the request to program the data, performing a coarse programming operation using a first type of programming scheme as a first programming phase associated with programming the data to the individual WL; and performing, as a second programming phase, a fine programming operation using a second type of programming scheme after performing the coarse programming operation to complete programming the data to the individual WL of the memory device.

Example 2. The system of Example 1, wherein the first type of programming scheme comprises an all level programming (ALP) scheme.

Example 3. The system of Example 2, wherein the ALP scheme applies programming pulses to program memory cells to their target levels in a single programming phase by controlling channel boosting for each target level.

Example 4. The system of any one of Examples 2-3, wherein the second type of programming scheme comprises an incremental step program pulse (ISPP) programming scheme.

Example 5. The system of Example 4, wherein the ISPP scheme uses a smaller voltage step size that is applied to the individual WL than the first type of programming scheme to achieve more accurate voltage threshold placement.

Example 6. The system of any one of Examples 1-5, wherein the coarse programming operation uses a larger voltage step size that is applied to the individual WL than the fine programming operation.

Example 7. The system of any one of Examples 1-6, wherein performing the coarse programming operation comprises controlling channel boosting for each target level during a voltage pass phase.

Example 8. The system of Example 7, wherein performing the coarse programming operation comprises applying a staircase waveform to the individual WL during the voltage pass phase.

Example 9. The system of Example 8, the operations comprising: applying a program pulse having a specified voltage step size to the individual WL following the staircase waveform.

Example 10. The system of any one of Examples 8-9, the operations comprising: performing program verify operations between programming loops during both the coarse and fine programming operations.

Example 11. The system of any one of Examples 1-10, the operations comprising: programming multiple sub-blocks of the individual WL in sequence.

Example 12. The system of Example 11, the operations comprising: alternating between programming the individual WL and a second WL that is adjacent to the individual WL.

Example 13. The system of any one of Examples 1-12, the operations further comprising: performing the coarse and fine programming operations on multiple sub-blocks of the individual WL in an interleaved sequence between multiple word lines.

Example 14. The system of Example 13, the operations further comprising: performing a first coarse programming operation using the first type of programming scheme on each sub-block (SB) including a first SB of the individual WL; after performing the first coarse programming operation on each SB of the individual WL, performing a second coarse programming operation using the first type of programming scheme on a first SB of an additional WL adjacent to the individual WL; performing a first fine programming operation using the second type of programming scheme on the first SB of the individual WL while performing a third coarse programming operation using the first type of programming scheme on a second SB of the additional WL; and performing a second fine programming operation using the second type of programming scheme on the first SB of the additional WL after the first fine programming operation is performed on each SB of the individual WL.

Example 15. The system of any one of Examples 1-14, the memory device comprising at least one of a multi-level cell (MLC) memory device, a tri-level cell (TLC) memory device, or quad-level cell (QLC) memory device.

Example 16. The system of any one of Examples 1-15, the memory device comprising a quad-level cell (QLC) memory device.

Example 17. The system of any one of Examples 1-16, wherein the memory device comprises a three-dimensional (3D) NAND device.

Example 18. At least one non-transitory machine-readable storage medium comprising instructions that, when executed by a processing device, cause the processing device to perform operations comprising: receiving a request to program data to an individual word line (WL) of a memory device; in response to receiving the request to program the data, performing a coarse programming operation using a first type of programming scheme as a first programming phase associated with programming the data to the individual WL; and performing, as a second programming phase, a fine programming operation using a second type of programming scheme after performing the coarse programming operation to complete programming the data to the individual WL of the memory device.

Example 19. A method comprising: receiving a request to program data to an individual word line (WL) of a memory device; in response to receiving the request to program the data, performing a coarse programming operation using a first type of programming scheme as a first programming phase associated with programming the data to the individual WL; and performing, as a second programming phase, a fine programming operation using a second type of programming scheme after performing the coarse programming operation to complete programming the data to the individual WL of the memory device.

Example 20. The method of Example 19, wherein the memory device comprises a 3D NAND device.

The term “coupled with” generally refers to a connection between components, which can be an indirect communicative connection or direct communicative connection (e.g., without intervening components), whether wired or wireless, including connections such as electrical, optical, magnetic, and the like.

“System data” hereinafter refers to data that is created and/or maintained by the memory sub-system for performing operations in response to host requests and for media management.

“User data” hereinafter generally refers to host data and garbage collection data.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

1. A system comprising:
a memory device; and
a processing device, operatively coupled to the memory device, configured programmed to cause the system to perform operations comprising:
receiving a request to program data to an individual word line (WL) of the memory device;
based on receiving the request to program the data, performing a coarse programming operation using a first type of programming scheme as a first programming phase associated with programming the data to the individual WL, the first type of programming scheme comprising an all level programming (ALP) scheme that simultaneously programs all target levels in a single programming phase by applying programming pulses and controlling channel boosting for each target level; and
performing, as a second programming phase, a fine programming operation using a second type of programming scheme after performing the coarse programming operation to complete programming the data to the individual WL of the memory device.

2. The system of claim 1, wherein controlling the channel boosting for each target level comprises toggling a bit line bias at different voltage pass (Vpass) thresholds while ramping a staircase Vpass applied to unselected word lines.

3. The system of claim 1, wherein controlling the channel boosting for each target level comprises activating different bit lines at different timing intervals during a voltage pass phase to establish different channel boosting potentials corresponding to respective target levels.

4. The system of claim 1, wherein the second type of programming scheme comprises an incremental step program pulse (ISPP) programming scheme.

5. The system of claim 4, wherein the ISPP scheme uses a smaller voltage step size that is applied to the individual WL than the first type of programming scheme to achieve more accurate voltage threshold placement.

6. The system of claim 1, wherein the coarse programming operation uses a larger voltage step size that is applied to the individual WL than the fine programming operation, wherein the coarse programming operation completes programming the data to the individual WL using a smaller number of programming pulses than the fine programming operation.

7. The system of claim 1, wherein performing the coarse programming operation comprises controlling channel boosting for each target level during a voltage pass phase.

8. The system of claim 7, wherein performing the coarse programming operation comprises applying a staircase waveform to the individual WL during the voltage pass phase.

9. The system of claim 8, the operations comprising:
applying a program pulse having a specified voltage step size to the individual WL following the staircase waveform.

10. The system of claim 8, the operations comprising:
performing program verify operations between programming loops during both the coarse and fine programming operations.

11. The system of claim 1, the operations comprising:
programming multiple sub-blocks of the individual WL in sequence, wherein performing the coarse programming operation comprises a seed phase in which a selected word line is initialized at a pass-seed voltage and bit lines are set to an inhibit voltage for cells to be inhibited and to a program-enable voltage for cells to be programmed, followed by a first voltage pass phase and a second voltage pass phase that adjust bit line biases to establish boosting potentials for respective target levels.

12. The system of claim 11, the operations comprising:
alternating between programming the individual WL and a second WL that is adjacent to the individual WL.

13. The system of claim 1, the operations further comprising:
performing the coarse and fine programming operations on multiple sub-blocks of the individual WL in an interleaved sequence between multiple word lines, wherein the fine programming operation using the second type of programming scheme on a sub-block of the individual WL is performed concurrently with the coarse programming operation using the first type of programming scheme on a sub-block of an additional WL.

14. The system of claim 13, the operations further comprising:
performing a first coarse programming operation using the first type of programming scheme on each sub-block (SB) including a first SB of the individual WL;
after performing the first coarse programming operation on each SB of the individual WL, performing a second coarse programming operation using the first type of programming scheme on a first SB of an additional WL adjacent to the individual WL;
performing a first fine programming operation using the second type of programming scheme on the first SB of the individual WL while performing a third coarse programming operation using the first type of programming scheme on a second SB of the additional WL; and
performing a second fine programming operation using the second type of programming scheme on the first SB of the additional WL after the first fine programming operation is performed on each SB of the individual WL.

15. The system of claim 1, the memory device comprising at least one of a multi-level cell (MLC) memory device, a tri-level cell (TLC) memory device, or quad-level cell (QLC) memory device.

16. The system of claim 1, the memory device comprising a quad-level cell (QLC) memory device.

17. The system of claim 1, wherein the memory device comprises a three-dimensional (3D) NAND device.

18. At least one non-transitory machine-readable storage medium comprising instructions that, when executed by a processing device, cause the processing device to perform operations comprising:
receiving a request to program data to an individual word line (WL) of a memory device;
based on receiving the request to program the data, performing a coarse programming operation using a first type of programming scheme as a first programming phase associated with programming the data to the individual WL, the first type of programming scheme comprising an all level programming (ALP) scheme that simultaneously programs all target levels in a single programming phase by applying programming pulses and controlling channel boosting for each target level; and
performing, as a second programming phase, a fine programming operation using a second type of programming scheme after performing the coarse programming operation to complete programming the data to the individual WL of the memory device.
receiving a request to program data to an individual word line (WL) of a memory device;
based on receiving the request to program the data, performing a coarse programming operation using a first type of programming scheme as a first programming phase associated with programming the data to the individual WL, the first type of programming scheme comprising an all level programming (ALP) scheme that simultaneously programs all target levels in a single programming phase by applying programming pulses and controlling channel boosting for each target level; and
performing, as a second programming phase, a fine programming operation using a second type of programming scheme after performing the coarse programming operation to complete programming the data to the individual WL of the memory device.

20. The method of claim 19, wherein the memory device comprises a three-dimensional (3D) NAND device.
